(19) United States
(12) Patent Application Publication
(10) Pub. No.: US 2015/0270201 A1
(43) Pub. Date: Sep. 24, 2015

(54) SEMICONDUCTOR MODULE PACKAGE AND METHOD OF MANUFACTURING THE SAME

(71) Applicant: SAMSUNG ELECTRO-MECHANICS CO., LTD., Suwon-Si (KR)

(72) Inventors: Kwang Soo Kim, Suwon-Si (KR); Joon Seok Chae, Suwon-Si (KR); Young Hoon Kwak, Suwon-Si (KR)

(73) Assignee: SAMSUNG ELECTRO-MECHANICS CO., LTD., Suwon-Si (KR)

(21) Appl. No.: 14/540,033

(22) Filed: Nov. 12, 2014

(30) Foreign Application Priority Data
Mar. 18, 2014 (KR) 10-2014-0031809

(51) Int. Cl. H01L 23/495; H01L 23/31; H01L 21/48; H01L 23/00; H01L 21/56; H01L 25/18; H01L 25/00; H01L 23/10; H01L 21/52

(52) U.S. Cl. CPC H01L 23/49568; H01L 23/10; H01L 23/3107; H01L 23/49575; H01L 21/4821; H01L 21/52; H01L 21/565; H01L 25/18; H01L 25/50; H01L 24/83; H01L 24/85; H01L 24/32; H01L 24/48; H01L 2224/83801; H01L 2224/48137; H01L 2924/0665; H01L 2924/01014

(57) ABSTRACT

There is provided a semiconductor module package including: a base substrate formed by mounting one or more first semiconductor devices thereon; a lead frame formed to have an end portion of one side connected to the base substrate and an end portion of the other side protruded to the outside; a supporting frame formed on a top surface of the first semiconductor device and having a first adjusting member formed to protrude to a lower portion thereof; and a mold part sealing the base substrate, the lead frame, and a portion of the supporting frame, wherein one or more of the first semiconductor devices are formed to have different steps from each other.

### CROSS-REFERENCE TO RELATED APPLICATION

This application claims the benefit of Korean Patent Application No. 10-2014-0031809, filed on Mar. 18, 2014, entitled “Semiconductor Module Package and Method of Manufacturing the Same” which is hereby incorporated by reference in its entirety into this application.

### BACKGROUND

The present disclosure relates to a semiconductor module package and a method of manufacturing the same.

In accordance with an increase in energy consumption around the world, an efficient use of restricted energy has been attracting much attention. Therefore, a use of an inverter adopting an intelligent power module (IPM) for efficiently performing power conversion of energy in the existing home and industrial appliances has accelerated. Since the inverter is directly related to reliability of a power semiconductor module, which is a key component, and performance of heat dissipation of the power semiconductor module, it has been highlighted as an importance issue together with high integration, high capacity, miniaturization, and high efficiency.

Regarding the reliability issue, a semiconductor device and a connecting terminal part are electrically connected by a wire bonding scheme. In this case, the wire bonding scheme frequently fails due to a coefficient of thermal expansion (CTE) and heat of the semiconductor device and the wire.

Recently, a research into a direct lead bonding method has been conducted to remove the wire bonding the semiconductor device. However, according to the lead bonding method, since a plurality of power semiconductors are mounted, a height difference has been generated. For example, among the power semiconductor devices, an insulated gate bipolar transistor (IGBT) has a step of 70 μm and a fast recovery diode (FRD) has the step of 150 μm to 200 μm. Therefore, problems such as a step adjusting problem upon manufacturing a lead frame, a process fail caused by stress against the lead frame directly bonded to the device, and the like have occurred.

### RELATED ART DOCUMENT

### Patent Document

(Patent Document 1) US2013-0221513 A1

### SUMMARY

An aspect of the present disclosure may provide a semiconductor module package capable of allowing heat dissipation of a lead frame and a supporting frame not to be concentrated by horizontally forming the supporting frame formed in the semiconductor module package.

According to an aspect of the present disclosure, a semiconductor module package may include: a base substrate formed by mounting one or more first semiconductor devices thereon; a lead frame formed to have an end portion of one side connected to the base substrate and an end portion of the other side protruded to the outside; a supporting frame formed on a top surface of the first semiconductor device and having a first adjusting member formed to be protruded to a lower portion thereof; and a mold part sealing the base substrate, the lead frame, and a portion of the supporting frame, wherein one or more of the first semiconductor devices are formed to have different steps from each other.

The supporting frame may have a top surface formed to be in parallel with a top surface of the base substrate.

The base substrate may include: a first insulating layer; a first pattern formed on an upper portion of the first insulating layer; a second insulating layer formed on upper portions of the first pattern and the first insulating layer; and a second pattern formed on an upper portion of the second insulating layer.

The first pattern may be formed on a bottom surface of the first semiconductor device and may be formed to discharge heat from the first semiconductor device to the outside.

The first semiconductor device may use a semiconductor device of a power series.

The first adjusting member may be formed to be in contact with the second insulating layer and the second pattern.

The semiconductor module package may further include a second semiconductor device controlling a current and a voltage in the first semiconductor device and formed on the second pattern.

The second semiconductor device may use a control device controlling the first semiconductor device.

The supporting frame may have a second adjusting member formed to correspond to the top surface of the first semiconductor device and to protrude to a lower end portion thereof

The first adjusting member may have a protruded length formed to be equal to or longer than that of the second adjusting member.

The second adjusting member and top surfaces of one or more of the first semiconductor devices may have a soldering formed therebetween.

The soldering may be formed to fill the same interval between the first semiconductor device and the second adjusting member.

The soldering may be made of an epoxy resin and a silicon resin.

According to another aspect of the present disclosure, a method of manufacturing a semiconductor module package may include: preparing a base substrate on which one or more first semiconductor devices and second semiconductor devices are mounted; forming lead frames at both sides of the base substrate; electrically connecting the second semiconductor device to the first semiconductor device and the lead frame; disposing a first adjusting member between the first semiconductor device and the first semiconductor device and forming a supporting frame on a top surface of the first semiconductor device; and forming a mold part sealing the supporting frame, the base substrate, the first semiconductor device, the second semiconductor device, and a portion of the lead frame.

The forming of the supporting frame on a top surface of the first semiconductor device may include bonding a second adjusting member on the top surface of the first semiconductor device using a soldering.

In the bonding of the second adjusting member on the top surface of the first semiconductor device using a soldering, the soldering may be bonded using an epoxy resin and a silicon resin.

In the forming of the supporting frame on a top surface of the first semiconductor device, the supporting frame may have a top surface formed to be in parallel with the base substrate.

The forming of the lead frames at both sides of the base substrate may include bending the lead frame by trimming and forming a portion thereof

The electrically connecting of the second semiconductor device to the first semiconductor device and the lead frame may include electrically connecting the second semiconductor device to the first semiconductor device and the lead frame using a wire.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a semiconductor module package according to an exemplary embodiment of the present disclosure;

FIG. 2 is a view illustrating a cross section on which a base substrate, a semiconductor, and a supporting frame of FIG. 1 are stacked;

FIG. 3 is a partially enlarged view of the part A of FIG. 1;

FIG. 4 is a view illustrating a cross section of the base substrate of FIG. 1;

FIG. 5 is a view illustrating a cross section of the supporting frame of FIG. 1;

FIG. 6 is a cross-sectional view of a semiconductor module package according to a second exemplary embodiment of the present disclosure; and

FIGS. 7 to 10 are views illustrating a method of manufacturing a semiconductor module package according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

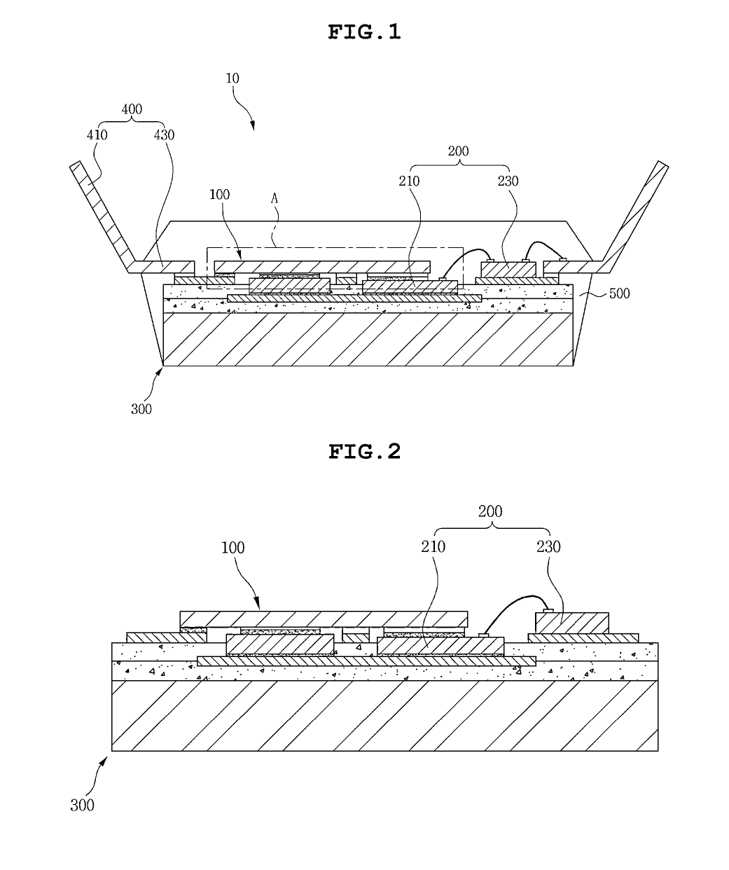

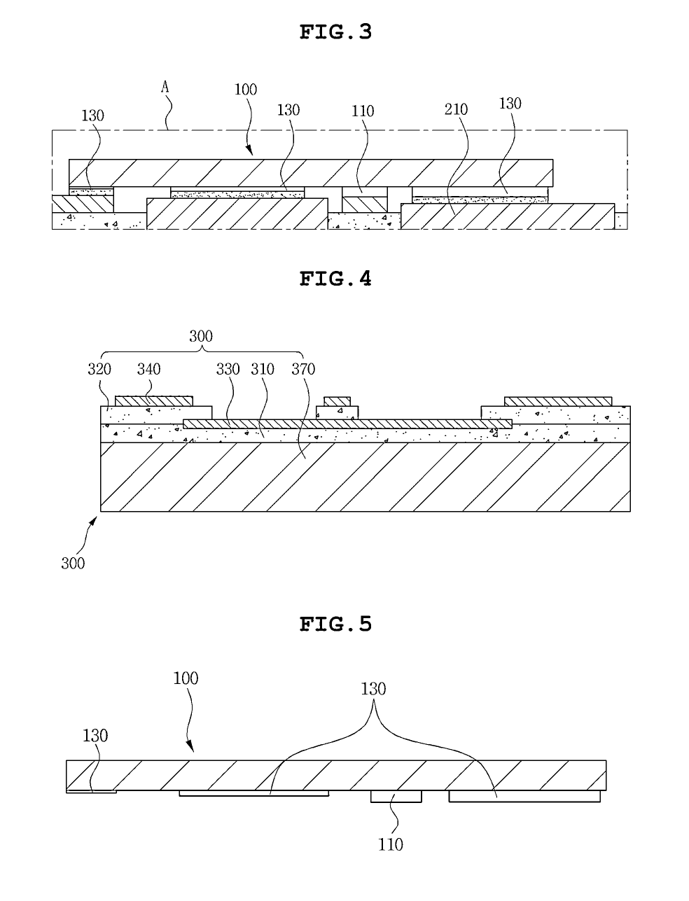

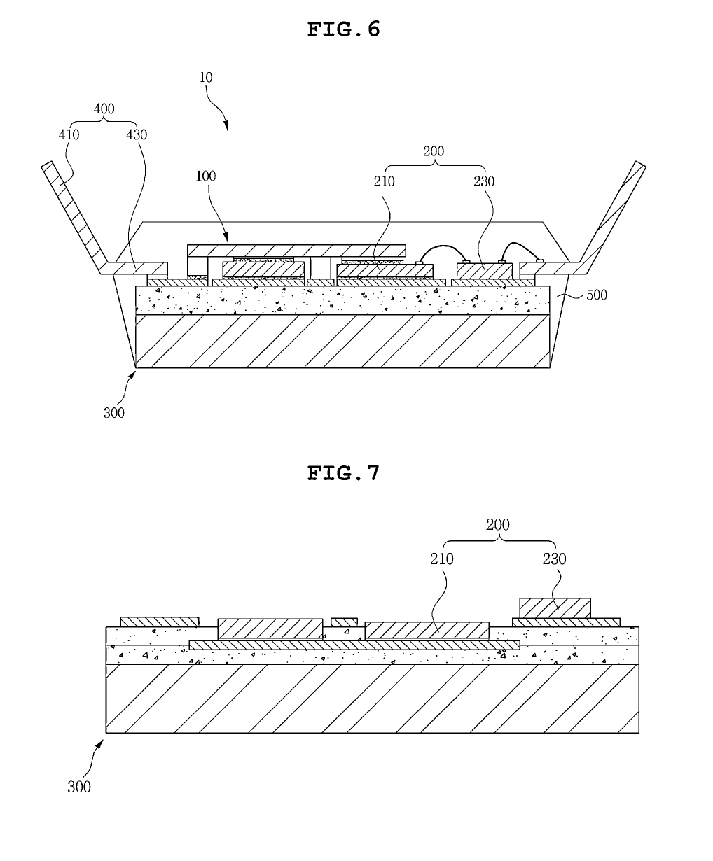

Hereinafter, exemplary embodiments of the present disclosure will be described in detail with reference to the accompanying drawings. FIG. 1 is a cross-sectional view of a semiconductor module package according to an exemplary embodiment of the present disclosure, FIG. 2 is a view illustrating a cross section on which a base substrate, a semiconductor, and a supporting frame of FIG. 1 are stacked, FIG. 3 is a partially enlarged view of the part A of FIG. 1, FIG. 4 is a view illustrating a cross section of the base substrate of FIG. 1, FIG. 5 is a view illustrating a cross section of the supporting frame of FIG. 1, FIG. 6 is a cross-sectional view of a semiconductor module package according to a second exemplary embodiment of the present disclosure, and FIGS. 7 to 10 are views illustrating a method of manufacturing a semiconductor module package according to an exemplary embodiment of the present disclosure.

The semiconductor module package according to an exemplary embodiment of the present disclosure includes a base substrate 300 formed by mounting one or more first semiconductor devices 210 thereon; a lead frame 400 formed to have an end portion of one side connected to the base substrate 300 and an end portion of the other side protruded to the outside; a supporting frame 100 formed on a top surface of the first semiconductor device 210 and having a first adjusting member 110 formed to protrude to a lower portion thereof; and a mold part 500 sealing the base substrate 300, the lead frame 400, and a portion of the supporting frame 100.

The base substrate 300 forms a conductor pattern. The base substrate 300 may be a printed circuit board, a ceramic substrate, or a metal board having an anodized layer, but is not particularly limited thereto. The base substrate 300, which is a circuit board on which one or more circuit layers including a connection pad is formed on an insulating layer, may be the printed circuit board. Although the present drawing shows a case in which a specific configuration of an internal circuit pattern is omitted for convenience of explanation, it is apparent that the circuit board on which one or more circuit layers are formed on the insulating layer is used as the base substrate.

The base substrate 300 may have a connection pad (not shown) formed on a second insulating layer 320. The connection pad (not shown) may be connected to an electronic component, a semiconductor device, and the lead frame.

The base substrate 300 according to an exemplary embodiment of the present disclosure includes a first insulating layer 310; a first pattern 330 formed on an upper portion of the first insulating layer 310; a second insulating layer 320 formed on upper portions of the first pattern 330 and the first insulating layer 310; and a second pattern 340 formed on an upper portion of the second insulating layer 320.

The first pattern 330 and the second pattern 340 may be formed in the conductor pattern (see FIG. 4). The first pattern 330 may be formed in a heat dissipation pattern by taking accounting of a heating value of the first semiconductor device 210 to be described below. The first pattern 330 and the second pattern 340 are not limited to the above-mentioned form.

The first pattern 330 and the second pattern 340 may be electrically connected or separately connected to the semiconductor device 200, respectively. In this case, when the first pattern 330 and the second pattern 340 are connected to the second semiconductor device 230, respectively, they may be connected by a wire bonding scheme. The wire bonding may be a metal material, for example, aluminum (Al), gold (Au), or an alloy thereof This does not limit an electrical connection or form of the base substrate 300, and any base substrate 300 and the circuit board may be used as long as they are used in the art.

The first insulating layer 310 and the second insulating layer 320 form slot spaces in which the electronic component and the semiconductor device 200 are mounted (see FIG. 4). The first semiconductor device 210 is formed to be inserted into the slot spaces of the first insulating layer 310 and the second insulating layer 320. The first insulating layer 310 and the second insulating layer 320 may be made of a complex polymer resin which is typically used as an interlayer insulating material. For example, the insulating layer may be made of a prepreg, Ajinomoto Build up Film (ABF), and an epoxy based resin such as FR-4, Bismaleimide Triazine (BT), or the like. In addition, the insulating layer may have a form of a substrate or a film. However, in an exemplary embodiment of the present disclosure, the material of forming the insulating layer and the form of the insulating layer are not limited thereto.

A heat sink or a heat dissipating plate 370 dissipating heat to the outside may be formed on a lower end portion of the base substrate 300. The base substrate 300 may discharge the heat generated from the electronic component and the semiconductor device 200 to the outside through the heat sink or the heat dissipating plate 370. In this case, the heat sink or the heat dissipating plate 370 may be made by using a material such as a metal, an aluminum alloy, or the like discharging the heat to the outside.

The lead frame 400 may be formed to be connected to any one of the base substrate 300, the electronic component, the semiconductor device 200, and the connection pad. The lead frame 400 is configured to include a plurality of leads, where the respective leads may include an external lead 410 connected to an external base substrate (not shown) and an internal lead 430 connected to the electronic component. The lead frame uses a special copper alloy, or the like made by using copper as a main raw material and mixing nickel, silicon, and phosphorus therewith.

The external lead frame 410 may refer to a portion exposed to an exterior of the mold part 500 to be described below and the internal lead frame 430 may refer to a portion disposed in the mold part 500. The external lead frame 410 is formed to be protruded to a radial outer side of the mold part 500. The external lead frame may be formed by being upwardly bent at one protruded end. In this case, the external lead frame is formed to be bent by performing a trimming process and a forming process (see FIG. 6).

The internal lead frame 430 may be mounted on one surface of the electronic component and the semiconductor device 200 and may be electrically connected thereto. In this case, the internal lead frame 430 may be electrically connected to the electronic component and the semiconductor device 200 by the wire bonding. This is not to limit the electrical connection between the internal lead frame 430, and the electronic component and the semiconductor device 200 to the above-mentioned electrical connection. The top surface of the lead frame 120 may be provided with mounting electrodes for mounting the electronic component and the semiconductor device 200 or circuit patterns (not shown) for electrically connecting the mounting electrodes to each other.

The supporting frame 100 is formed in the mold part 500. When a plurality of first semiconductor devices (insulated gate bipolar transistor (IGBT), metal-oxide semiconductor field-effect transistor (MOSFET), fast recovery diode (FRD), diode) are disposed in a different kinds from each other, the supporting frame 100 removes height steps between the first semiconductor devices 210 which are different from each other (see FIGS. 2 to 6).

The supporting frame 100 may be electrically connected to the electronic component and the semiconductor device 200. The supporting frame 100 uses a special copper alloy, or the like made by using copper as a main raw material and mixing nickel, silicon, and phosphorus therewith. The mounting electrodes for mounting the electronic component and the semiconductor device 200 may be formed on a top surface and a bottom surface of the supporting frame 100. In addition, the circuit patterns (not shown) electrically connecting the mounting electrodes to each other may be formed on the top surface and the bottom surface of the supporting frame 100.

The supporting frame 100 is formed to be in parallel with the top surface of the first semiconductor device. The supporting frame 100 includes a first adjusting member 110 formed to maintain horizontality with the base substrate 300 and a second adjusting member 130 formed to correspond to the first semiconductor device 210.

The first adjusting member 110 serves as a supporter so that the top surface of the supporting frame 100 is horizontal. The first adjusting member 110 is formed to protrude to the lower end portion thereof so as to be in contact with the base substrate 300. The first adjusting member 110 is formed to be in contact with the second insulating layer 330 or the second pattern 340. The first adjusting member 110 may be formed between the first semiconductor device 210 and the first semiconductor device 210. The first adjusting member 110 is formed to have a protruded length equal to or longer than that of the second adjusting member 130.

The second adjusting member 130 corresponds to a height of one or more first semiconductor devices 210. That is, the second adjusting member 130 allows the supporting frame 100 to be in contact with the first semiconductor device 210 while maintaining the supporting frame 100 in a horizontal state. The second adjusting members 130 are formed to correspond to the top surfaces of the plurality of first semiconductor devices 210 which are disposed.

A soldering 250 (adhesive material) is formed between the second adjusting member 130 and the top surface of the semiconductor device 200. The second adjusting member 130 has the soldering 250 formed thereon so that the first semiconductor device 210 may perform electrical conduction and heat dissipation. The soldering 250 uniformly fills a distance between the lower end portion of the second adjusting member 130 and the top surface of the first semiconductor device 210. The second adjusting member 130 forms an applied thickness of the soldering 250 to be constant. This is to allow the thickness of the soldering 250 to be constant and improve electrical reliability. In addition, this may prevent an occurrence of concentrated stress and concentration of heating portions, which are problems that occur at the time of differently forming the thickness of the soldering 250, in advance. The second adjusting member 130 is formed to have a protruded length equal to or shorter than that of the first adjusting member 110.

The semiconductor device 200 may include various devices such as passive devices, active devices, and the like. The semiconductor device 200 includes a first semiconductor device 210 and a second semiconductor device 230. The first semiconductor device 210 and the second semiconductor device 230 may be used as at least one of a power device and a control device. This is only an example, and is not to limit a kind of semiconductor device 200 mounted on a semiconductor module package 10.

One or more first semiconductor devices 210 are formed on the top surface of the base substrate 300. The first semiconductor device 210 is formed to be inserted into the slot space of the base substrate 300 (see FIG. 1). In addition, the first semiconductor device 210 may be formed on the top surface of the base substrate (see FIG. 6).

As the first semiconductor device 210, one of the insulated gate bipolar transistor (IGBT), the MOSFET, the FRD, the diode, and the like which are power device series may be used. For example, when the IGBT device (having a height of 70 μm) and the FRD device (having a height of 150 μm to 200 μm), which are the first semiconductor device 210, are mounted on the base substrate, a step height of 80 μm to 120 μm may be generated. In order to remove the above-mentioned step height, the supporting frame 100 is formed.

The second semiconductor device 230 is electrically connected to the lead frame 400 and the first semiconductor device 210. As the second semiconductor device 230, a control integrated circuit (IC) of a control device series is used. The second semiconductor device 230 prevents a sharp change in a current flowing in the device. The second semiconductor device 230 is formed to be mounted on the top surface of the base substrate 300 and is formed to use the control device. The second semiconductor device 230 uses power less than the first semiconductor device 210. This is to allow the second semiconductor device 230 to prevent a sharp change in a current and a voltage of the first semiconductor device 210.

The second semiconductor device 230 controls the current and the voltage supplied from the outside. The second semiconductor device 230 serves to absorb a surge voltage or ringing voltage. In this case, as the second semiconductor device 230, a snubber may be used. This is not to limit the second semiconductor device 230 to the snubber. A plurality of semiconductor devices 200 may be mounted in the semiconductor module package 10.

The molding part 500 is formed to apply the first semiconductor device 210 and the portion of the lead frame 400. The molding part 500 may be made of silicone gel, an epoxy molded compound (EMC), or the like, but is not particularly limited thereto. The molding part 500 may be formed to expose one surface of the base substrate 300.

A method of manufacturing a semiconductor module package will be described with reference to FIGS. 7 to 10. The method of manufacturing the semiconductor module package according to an exemplary embodiment of the present disclosure includes preparing a base substrate 300 on which one or more first semiconductor devices 210 and second semiconductor devices 230 are mounted; forming lead frames 400 at both sides of the base substrate 300; electrically connecting the second semiconductor device 230 to the first semiconductor device 210 and the lead frame 400; disposing a first adjusting member 110 between the first semiconductor device 210 and the first semiconductor device 210 and forming a supporting frame 100 on a top surface of the first semiconductor device 210; and forming a mold part 500 sealing the supporting frame 100, the base substrate 300, the first semiconductor device 210, the second semiconductor device 230, and a portion of the lead frame 400.

FIG. 7 is a view showing a case in which the first semiconductor device and the second semiconductor device are mounted on a surface of the base substrate. The first semiconductor device 210 is inserted into an internal slot space of the base substrate 300. In this case, a plurality of first semiconductor devices 210, which are different kinds of devices, are inserted. That is, the plurality of first semiconductor devices 210 maintain a height step between each other. The second semiconductor device 230 is mounted on one side or both sides of the base substrate 300.

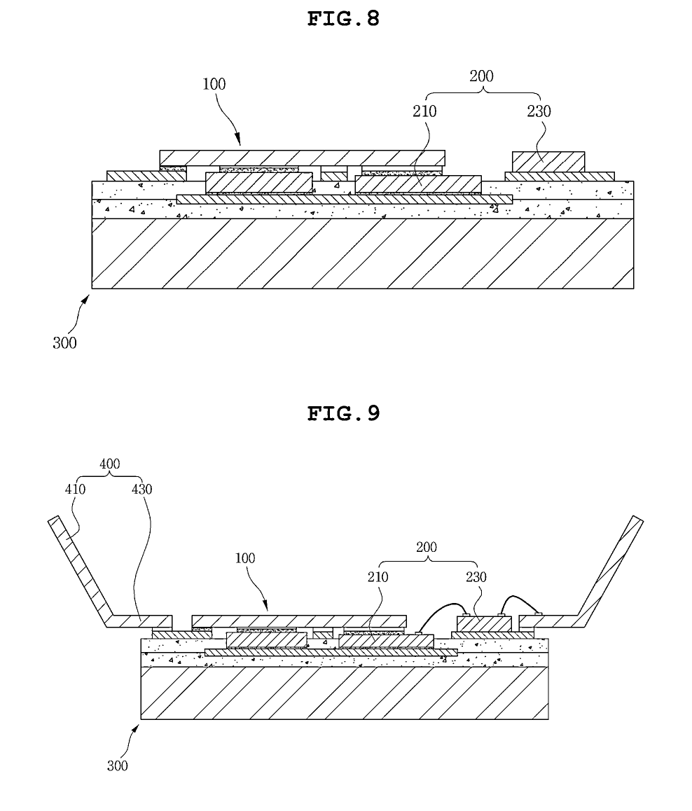

FIG. 8 is a view showing a case in which the supporting frame is mounted on the surface of the base substrate. Soldering 250 is formed on one side of the base substrate 300, an electronic component, and the semiconductor device 200 so as to have a constant thickness. The supporting frame 100, the base substrate 300, and the first semiconductor device 210 are bonded to one another by using the soldering 250. The soldering 250 may be bonded using an epoxy resin and a silicon resin.

The supporting frame 100 is formed to be in parallel with the base substrate 300. That is, the supporting frame 100 is mounted on the first semiconductor device 210. In this case, the second adjusting member 130 is mounted on the first semiconductor device 210 while the first adjusting member 110 is in contact with the base substrate 300.

FIG. 9 is a view showing a case in which the lead frame is mounted on the base substrate. The lead frame 400 is electrically formed on one side and the other side of the base substrate 300. In this case, the lead frame 400 which is bent by performing a trimming process and a forming process for a portion thereof may be used. The second semiconductor device 230 is electrically connected to the first semiconductor device 210 and the lead frame 400. In this case, the second semiconductor device 230 is electrically connected to the first semiconductor device 210 and the lead frame 400 using a wire.

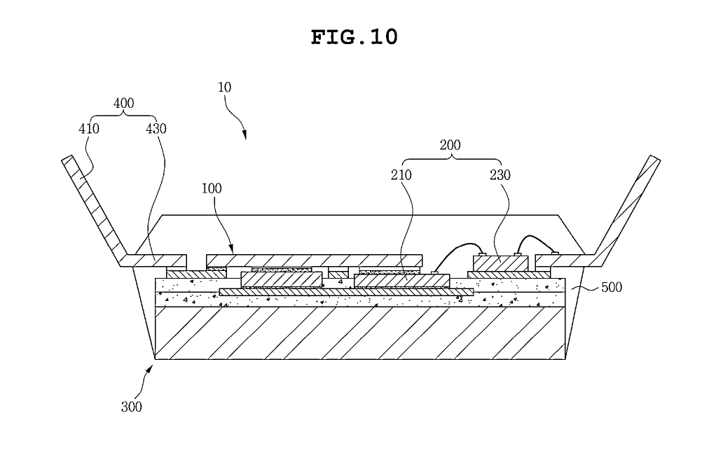

FIG. 10 is a view showing a case in which the molding part is formed on the lead frame and the base substrate. The molding part 500 is formed to apply the first semiconductor device 210 and a portion of the lead frame 400. The molding part 500 may be made of silicone gel, an epoxy molded compound (EMC), or the like, but is not particularly limited thereto. The molding part 500 may be formed to expose one surface of the base substrate 300.

As set forth above, according to the exemplary embodiments of the present disclosure, the semiconductor module package may suppress a phenomenon in which the heating of the lead frame and the supporting frame is concentrated, by horizontally forming the supporting frame formed in the semiconductor module package.

In addition, the semiconductor module package according to an exemplary embodiment of the present disclosure may prevent damage for the power device caused by stress in the process, by horizontally forming the supporting frame having the first adjusting member and the second adjusting member formed in the semiconductor module package.

In addition, the semiconductor module package according to an exemplary embodiment of the present disclosure may maintain a constant bonding height of the soldering part formed between the semiconductor device and the supporting frame, by horizontally forming the supporting frame having the first adjusting member and the second adjusting member formed in the semiconductor module package.

In addition, the semiconductor module package according to an exemplary embodiment of the present disclosure may design the circuit pattern by a multilayer heat dissipation substrate, by horizontally forming the supporting frame having the first adjusting member and the second adjusting member formed in the semiconductor module package.

In addition, the semiconductor module package according to an exemplary embodiment of the present disclosure may decrease an electrical error generated between a plurality of semiconductor devices, by horizontally forming the supporting frame having the first adjusting member and the second adjusting member formed in the semiconductor module package.

In addition, the semiconductor module package according to an exemplary embodiment of the present disclosure may easily mount the supporting frame, by horizontally forming the supporting frame having the first adjusting member and the second adjusting member formed in the semiconductor module package.

In addition, the semiconductor module package according to an exemplary embodiment of the present disclosure may solve a phenomenon in which the heat is concentrated to minimize performance degradation in the semiconductor device, by horizontally forming the supporting frame having the first adjusting member and the second adjusting member formed in the semiconductor module package.

In addition, the semiconductor module package according to an exemplary embodiment of the present disclosure may suppress a phenomenon in which heating parts of the wire bonding are concentrated, by horizontally forming the supporting frame having the first adjusting member and the second adjusting member formed in the semiconductor module package.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A semiconductor module package comprising:
a base substrate formed by mounting one or more first semiconductor devices thereon;
a lead frame formed to have an end portion of one side connected to the base substrate and an end portion of the other side protruded to the outside;
a supporting frame formed on a top surface of the first semiconductor device and having a first adjusting member formed to be protruded to a lower portion thereof; and
a mold part sealing the base substrate, the lead frame, and a portion of the supporting frame,
wherein one or more of the first semiconductor devices are formed to have different steps from each other.

2. The semiconductor module package of claim 1, wherein the supporting frame has a top surface formed to be in parallel with a top surface of the base substrate.

3. The semiconductor module package of claim 1, wherein the base substrate includes:
a first insulating layer;
a first pattern formed on an upper portion of the first insulating layer;
a second insulating layer formed on upper portions of the first pattern and the first insulating layer; and
a second pattern formed on an upper portion of the second insulating layer.

4. The semiconductor module package of claim 3, wherein the first pattern is formed on a bottom surface of the first semiconductor device and is formed to discharge heat from the first semiconductor device to the outside.

5. The semiconductor module package of claim 3, wherein the first semiconductor device uses a semiconductor device of a power series.

6. The semiconductor module package of claim 3, wherein the first adjusting member is formed to be in contact with the second insulating layer and the second pattern.

7. The semiconductor module package of claim 3, further comprising a second semiconductor device controlling a current and a voltage in the first semiconductor device and formed on the second pattern.

8. The semiconductor module package of claim 7, wherein the second semiconductor device uses a control device controlling the first semiconductor device.

9. The semiconductor module package of claim 1, wherein the supporting frame has a second adjusting member formed to correspond to the top surface of the first semiconductor device and to protrude to a lower end portion thereof.

10. The semiconductor module package of claim 9, wherein the first adjusting member has a protruded length formed to be equal to or longer than that of the second adjusting member.

11. The semiconductor module package of claim 10, wherein the second adjusting member and top surfaces of one or more of the first semiconductor devices have a soldering formed therebetween.

12. The semiconductor module package of claim 11, wherein the soldering is formed to fill the same interval between the first semiconductor device and the second adjusting member.

13. The semiconductor module package of claim 11, wherein the soldering is made of an epoxy resin and a silicon resin.

14. A method of manufacturing a semiconductor module package, the method comprising:
preparing a base substrate on which one or more first semiconductor devices and second semiconductor devices are mounted;
forming lead frames at both sides of the base substrate;
electrically connecting the second semiconductor device to the first semiconductor device and the lead frame;
disposing a first adjusting member between the first semiconductor device and the first semiconductor device and forming a supporting frame on a top surface of the first semiconductor device; and
forming a mold part sealing the supporting frame, the base substrate, the first semiconductor device, the second semiconductor device, and a portion of the lead frame.

15. The method of claim 14, wherein the forming of the supporting frame on a top surface of the first semiconductor device includes bonding a second adjusting member on the top surface of the first semiconductor device using a soldering.

16. The method of claim 15, wherein in the bonding of the second adjusting member on the top surface of the first semiconductor device using a soldering, the soldering is bonded using an epoxy resin and a silicon resin.

17. The method of claim 15, wherein in the forming of the supporting frame on a top surface of the first semiconductor device, the supporting frame has a top surface formed to be in parallel with the base substrate.

18. The method of claim 14, wherein the forming of the lead frames at both sides of the base substrate includes bending the lead frame by trimming and forming a portion thereof.

19. The method of claim 14, wherein the electrically connecting of the second semiconductor device to the first semiconductor device and the lead frame includes electrically connecting the second semiconductor device to the first semiconductor device and the lead frame using a wire.
